(19) United States
(12) Patent Application Publication
(10) Pub. No.: US 2010/0044726 A1
(43) Pub. Date: Feb. 25, 2010

(54) Method for Packaging White-Light LED and LED Device Produced Thereby

(76) Inventors: Qing LI, Blacksburg, VA (US); Binhai Yu, Foshan (CN); Junzheng Li, Foshan (CN); Lifang Liang, Foshan (CN)

Correspondence Address: LATIMER & MAYBERRY IP LAW, LLP, 13873 PARK CENTER ROAD, SUITE 106, HERNDON, VA, 20171, US

(21) Appl. No.: 12/370,685

(22) Filed: Feb. 13, 2009

Related U.S. Application Data
(60) Provisional application No. 61/091,072, filed on Aug. 22, 2008.

(30) Foreign Application Priority Data
Sep. 5, 2008 (CN) 200810141820.7

(51) Int. Cl. H01L 33/00

(52) U.S. Cl. 257/88; 438/118; 257/98; 257/E33.058; 257/E33.055

(57) ABSTRACT

This invention relates to light-emitting diodes or devices (LEDs), such as LED lighting assemblies and methods of manufacturing them. More particularly, this invention relates to white-light LED lighting assemblies, devices, and components, methods for packaging white-light LEDs, and LED devices produced thereby. A method for packaging a white-light LED is provided comprising providing a substrate with a resin injection hole and a vent hole, a packaging housing, at least one LED chip, a supporting frame and resin, installing the LED chip on the substrate, coating an inner wall of the packaging housing with fluorescent powder, connecting the packaging housing to the substrate by way of the supporting frame, so that a cavity is formed therebetween, injecting the resin into the cavity between the packaging housing and the substrate by way of the resin injection hole so that gas within the cavity is discharged by way of the vent hole, and curing the resin. LED assemblies made according to this method are also provided.

### CROSS-REFERENCE TO RELATED APPLICATIONS

This application relies on the disclosure and claims the benefit of the filing date of Chinese Patent Application No. 200810141820.7 filed Sep. 5, 2008 and of U.S. Provisional Application No. 61/091,072 filed Aug. 22, 2008, the disclosures of which are hereby incorporated by reference in their entireties.

### BACKGROUND OF THE INVENTION

1. Field of the Invention

This invention relates to light-emitting diodes or devices (LEDs), such as LED lighting assemblies and methods of manufacturing them. More particularly, this invention relates to white-light LED lighting assemblies, devices, and components, methods for packaging white-light LEDs, and LED devices produced thereby.

2. Description of the Related Art

In 1996, Nichia Chemical Industries in Japan developed a white-light LED by covering a blue LED with phosphor thereby mixing blue light and yellow light to create high brightness white light. Nowadays, the white-light LED is widely used for illumination.

Packaging is a very important process in producing the white-light LED. Conventionally, a packaging process comprises dropping transparent glue on a surface of an LED chip and coating the transparent glue with fluorescent powder. There are disadvantages, however, with such a method, including that the process is complex, and heat dispersion and light emission efficiency are poor, which makes it generally unsuitable for mass serial production. A similar known packaging method is described, for example, in U.S. Pat. No. 7,470,935.

Moreover, white-light LEDs, devices, components, and assemblies prepared by conventional packaging methods often exhibit undesirable characteristics, including that such devices are typically of complex structure, have low light emission efficiency, and have non-uniform chromatic light, which affect performance and popularity of the white-light LED.

### SUMMARY OF THE INVENTION

In view of the above-described issues with conventionally-prepared white-light LED assemblies and devices, it is an objective of the present invention to provide a method for packaging a white-light LED comprising a simple production process, good heat dispersion, and high light emission efficiency, which is especially suitable for mass serial production.

It is another objective of the present invention to provide an LED device with simple structure, high light emission efficiency, and uniform chromatic light.

In accordance with one embodiment of the invention, provided is a method for packaging a white-light LED, comprising providing a substrate with a resin injection hole and a vent hole, a packaging housing, at least one LED chip, a supporting frame, and resin, and installing the LED chip on the substrate, coating an inner wall of the packaging housing with fluorescent powder, connecting the packaging housing to the substrate by way of the supporting frame, so that a cavity is formed therebetween, injecting the resin into the cavity between the packaging housing and the substrate by way of the resin injection hole so that gas within the cavity is discharged by way of the vent hole, and curing the resin.

Further, in one embodiment, installing an LED chip (semiconductor chip) on the substrate can comprise providing an adhesive on a concave part of the substrate, attaching the LED chip to the adhesive, and connecting electrodes on the LED chip to a conductive layer on the substrate.

In a further embodiment, coating an inner wall of the packaging housing with fluorescent powder can comprise combining inorganic non-baking glue, non-baking consolidant, non-baking dispersants, non-baking plasticizer and fluorescent powder into a mixture, adding ceramic grinding balls to the mixture and stirring using, for example, a ball-milling method. Optionally continuous stirring of the mixture can be employed to deter or prevent the fluorescent powder from precipitating. An inner wall of the packaging housing can be coated with the fluorescent powder coating mixture and the coating can be exposed to air, so as to dry or partially dry the coating and fix it onto the packaging housing. A fan can be used to provide a stream of air for exposing the coating to air for a time sufficient to stiffen said coating sufficiently so as to fix the coating on the packaging housing and make the coating immobile in shape. The coating can be cured by exposing the packaging housing to air, preferably hot and dry, or by putting the packaging housing into an oven. Excess or residual fluorescent powder can be removed from the packaging housing, if desired, after the fluorescent powder coating dries by evaporation.

In one embodiment, connecting the packaging housing to the substrate by way of a supporting frame, so that a cavity is formed therebetween, can comprise coating or plating part of the inner wall of the supporting frame with high reflecting material(s), installing the supporting frame on the substrate and installing the packaging housing on the supporting frame.

In embodiments, the supporting frame can be combined with the substrate by PLCC packaging.

In embodiments, the packaging housing can be installed on the supporting frame in a manner of interference fit.

Additionally, in embodiments, the packaging housing can be installed on the supporting frame in a manner of adhesion.

In accordance with the invention, LED devices are provided which comprise a substrate having at least one resin injection hole and at least one vent hole, at least one or a plurality of LED chips, a packaging housing and a supporting frame, wherein the supporting frame connects the packaging housing to the substrate, fluorescent powder is coated on an inner wall of the packaging housing, and resin is injected between the packaging housing and the substrate, so as to separate the LED chip from the fluorescent powder.

In embodiments of the invention, an upper surface of the substrate (typically the surface of the substrate intended to face the inner wall of the packaging housing) can comprise at least one or a plurality of concave depressions. The concave depressions operate to receive the LED chip(s) and can correspond in number with the number of desired LED chips. Optionally, a reflecting layer can be disposed on the outer surface of the concave depression.

Even further, according to the invention, embodiments can comprise a substrate comprising a printed circuit board (PCB), optionally with heat sink capabilities, a ceramic substrate, a metal circuit board, or a metal frame.

In embodiments of the invention, the substrate or a cross section of the substrate can be any shape, for example, rectangular, square, or circular, with a rectangular or circular shape being preferred.

In embodiments of the invention, the surface of the supporting frame can be configured so as to provide means or partial means for supporting the packaging housing and maintaining the packaging housing at a desired distance from the substrate when the LED device components are assembled. For example, the supporting frame can be shaped similar to a picture frame and comprise an upper surface defined by two surfaces, wherein a first surface lies in one horizontal plane and the second surface is interiorly concentric with the first surface and in a lower horizontal plane so as to form a step down from the first surface. The interior outline of the first surface defined by the step down of the second surface can comprise a shape which is complementary in shape to the outline of the packaging housing. The interior outline of the first surface and the stepped down second surface can together provide means for receiving and supporting the packaging housing within the supporting frame, i.e., the surface that faces the substrate when the LED device is assembled. Likewise, the invention includes a supporting frame capable of supporting the packaging housing in a similar manner but on the lower surface of the supporting frame. In a preferred embodiment, the supporting frame comprises means for receiving and supporting the packaging housing by way of the upper surface of the supporting frame, i.e., the surface that faces away from the substrate when the LED device components are assembled.

In embodiments of the invention, a plurality of positioning pins can be disposed on a lower surface of the supporting frame, i.e., the surface of the supporting frame that faces the substrate when the LED device components are assembled, so as to maintain a desired spacing between the packaging housing and the substrate and/or LED chips. This spacing, or cavity formed between the packaging housing and the substrate, provides for separation between the LED chips and the fluorescent powder coating by providing a cavity capable of being filled with resin to maintain the separation.

Even further, in embodiments, a plurality of positioning holes can be disposed on the substrate for receiving the positioning pins. Positioning holes can be holes that traverse the substrate and/or depressions in the substrate, typically complimentary in shape to the corresponding positioning pins.

In some embodiments, the substrate is combined with the substrate in a manner of PLCC packaging, wherein the substrate is a metal frame and the supporting frame is made of plastic.

Other embodiments can further comprise a supporting frame comprising high reflecting materials, which can be due to the material of the supporting frame itself or the inner wall (wall that faces the substrate when assembled) of the supporting frame can comprise a highly reflective material, for example, the inner wall of the supporting frame can be coated with a highly reflective material.

In a class of this embodiment or in another embodiment, the resin is made of transparent and soft silica.

In a class of this embodiment or in another embodiment, the packaging housing is made of glass.

In a class of this embodiment or in another embodiment, an outer surface of the packaging housing is planar free.

In a class of this embodiment or in another embodiment, the LED chips are disposed on the substrate in a rectangular or circular manner.

The method for packaging a white-light LED of the invention features a simple production process and is especially suitable for mass serial production and packaging having multiple chips, large area and white light generated by activating fluorescent powder with LED chips. Moreover, products produced by the method tend to have good luminous efficiency and heat dissipation performance. In addition, color and brightness of the white light are improved. One feature of the LED devices of the invention is the simple structure. Since the fluorescent powder is disposed on the inner wall of the packaging housing, the LED device emits white light with uniform chromatic light. In addition, the resin disposed between the packaging housing and the substrate improves heat dispersion and light emission efficiency of the LED device.

### BRIEF DESCRIPTION OF THE DRAWINGS

FIG. 1 is a flowchart of a method for packaging a white-light LED of an exemplary embodiment of the invention.

FIG. 2 is a detailed flowchart of a step S102 in FIG. 1.

FIG. 3 is a detailed flowchart of a step S103 in FIG. 1.

FIG. 4 is a detailed flowchart of a step S104 in FIG. 1.

FIG. 5 is a schematic view of LED components of an exemplary embodiment of the invention.

FIG. 6 is an assembly view of LED components in FIG. 5.

FIG. 7A is a schematic view of a substrate in FIG. 5.

FIGS. 7B-F are schematic views of other exemplary embodiments of substrates of the invention.

FIG. 8 is a schematic view of a resin injection process.

FIG. 9 is a top view of LED components of another exemplary embodiment of the invention.

### DETAILED DESCRIPTION OF VARIOUS EMBODIMENTS OF THE INVENTION

Reference will now be made in detail to various exemplary embodiments of the invention. The following detailed description is presented for the purpose of describing certain embodiments in detail. Thus, the following detailed description is not to be considered as limiting the invention to the embodiments described. Rather, the true scope of the invention is defined by the claims.

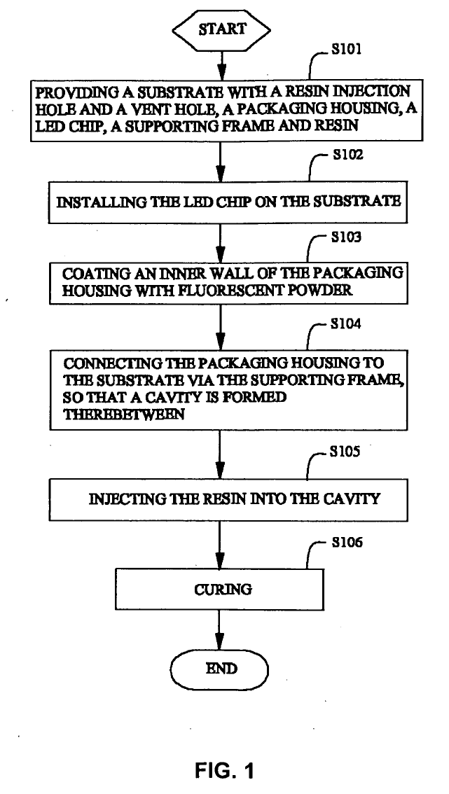

As shown in FIG. 1, in step S101, one or more components are provided. The components can comprise a substrate with at least one resin injection hole and at least one vent hole, a packaging housing, at least one LED chip, a supporting frame, and resin. The resin injection hole(s) and the vent hole(s) are both through holes. In another embodiment, the resin injection hole(s) and the vent hole(s) can be interchangeable with one another. Depending on the embodiment, one or more of these components can be provided individually or one or more may be provided together if previously combined. For example, the packaging housing and supporting frame may be provided pre-assembled or as one component.

In step S102, one or more LED chip(s) can be installed on the substrate, or can be provided as part of the substrate, for example, if previously installed or otherwise incorporated into or combined with the substrate.

In step S103, fluorescent powder can be coated on an inner wall of the packaging housing, which can be can be made of glass or other equivalent material, including but not limited to various plastics.

In step S104, the packaging housing can be connected to the substrate, for example as in this embodiment, by way of the supporting frame, so that a cavity is formed between the packaging housing and the substrate.

In step S105, the resin can be injected into the cavity formed between the substrate and the packaging housing by way of the resin injection hole(s) and gas within the cavity can be discharged by way of the vent hole(s). In embodiments, material injected into the cavity between the substrate and packaging housing can consist essentially of resin, i.e., not comprise fluorescent material. In this embodiment, the resin is made of transparent and soft silica. Compared with protected gas, thermal conductivity of the silica is even greater, and thus heat dissipation performance of the silica is even better. Moreover, since the refractive index of the silica is between that of the packaging housing and that of the LED chip, while refractive index of the protected gas is close to that of air, luminous efficiency of the silica is even better.

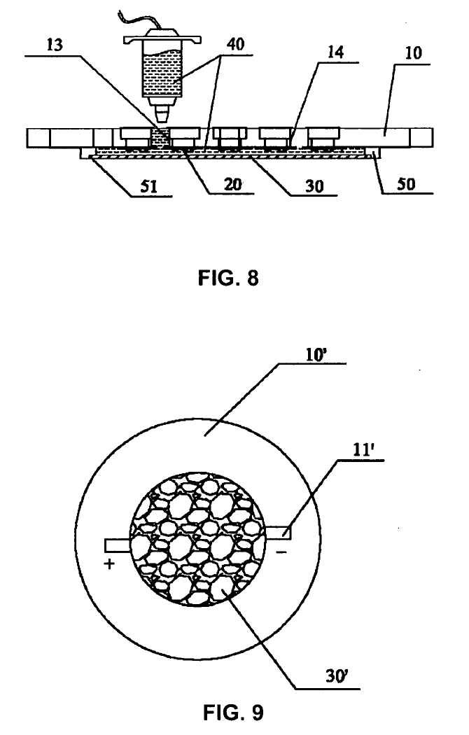

During the resin injection process, the resin can be injected from a bottom surface of the substrate, as shown in FIG. 8, with the components inverted from their orientation described in FIG. 5. Under the action of external pressure, the resin enters the cavity by way of the resin injection hole, forces the air to discharge through the vent hole, and fills up the cavity gradually. In this embodiment, the packaging housing, substrate, and LED chip are combined together with the resin, and packaging is implemented.

It should be noted that the resin injection process can be performed manually or mechanically.

Optionally, step S106 shows one embodiment in which the resin can be cured. The curing processing generally enables LED components to have higher intensity and reliability. In embodiments, curing can be performed by way of high-temperature baking. In other embodiments, ambient curing can also be employed. For example, the resin can be cured by way of high temperature baking in an oven at about 150+5° C., or at ambient temperature, such as about 25° C. The curing temperature is not critical and typically will depend on the resin material being cured. Indeed, any temperature from approximately room temperature to a high baking temperature, such as from 25° C. to 200° C., or any temperature in this range can be used depending on the specific resin material, other components of the assembly, and certain applications.

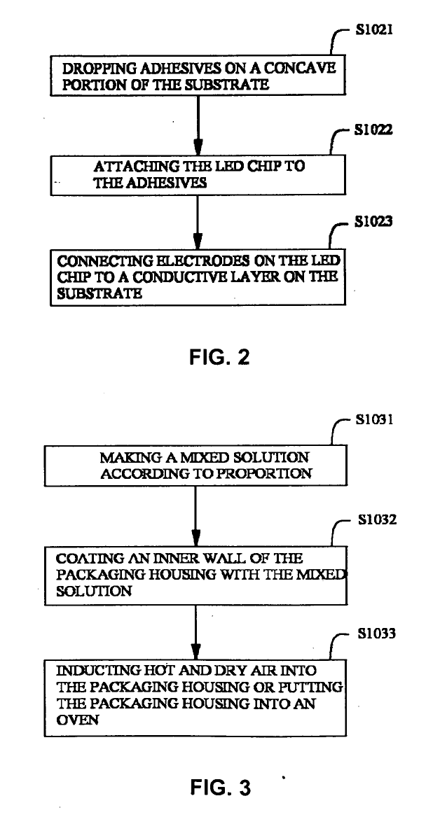

As shown in FIG. 2, in step S1021, the LED chips can optionally be installed on the substrate by using adhesives. For example, adhesives can be applied by dropping an adhesive on one or a plurality of concave parts of the substrate. In this embodiment, the adhesive is conductive silver paste. In other embodiments, other adhesives can also be used as appropriate. It will be appreciated that adhesives can be applied in various ways, including for example by spraying, dropping, brushing, and wiping to name a few, and certain application methods may be more appropriate than others depending on the type of adhesive and/or a particular application. Further, for example, the adhesive can be applied to the substrate and/or to the bottom outside surface of the LED chip prior to installation on the substrate. In step S1022, the LED chip can be attached to the substrate by way of adhesive. In step S1023, the LED chip can be in communication with the electrically conductive pathway of the substrate. For example, electrodes on the LED chip can be connected to a conductive layer on the substrate by way of metal wires so that a loop is formed therebetween. In embodiments, the LED chips can be installed on the substrate by using one step and/or one material for fixing the LED chips in place on the substrate and for completing the electrical connection between the conductive layer on the substrate and the electrodes on the LEDs.

As shown in FIG. 3, in step S1031, inorganic non-baking glue, non-baking consolidant, non-baking dispersants, non-baking plasticizer and fluorescent powder are combined as a mixture. The amount of each component of the mixture yields a mixture appropriate for creating a suitable coating comprising the fluorescent powder. Suitable mixtures comprise components in amounts that yield fluorescent powder coatings with a sufficient amount of the power dispersed throughout the coating and with adhesive properties capable of binding the coating to the surface of the packaging housing. Amounts of fluorescent powder, dispersants, adhesives, etc. may depend on the particular lighting application and/or the particular packaging housing materials being used. Ceramic grinding balls are added to the mixture, which is stirred by way of a ball-milling method. It is preferred that the fluorescent powder coating mixture be continuously stirred to prevent or deter precipitation of the fluorescent powder from the mixture.

In step S1032, an inner wall of the packaging housing is coated with the mixture and air is blown on the coating to assist with fixing the coating in place on the inner wall of the packaging housing and making the coating immobile in shape. The amount of fluorescent powder in the coating and/or the amount of coating applied to the packaging housing can be adjusted for particular applications. In an exemplary embodiment, the fluorescent powder coating can be applied to the packaging housing with a thickness of the applied coating in the range of, for example, about 5 to 500 microns. Any thickness in this range can be used for the coating. Even further, various desirable thicknesses can be determined by the amount of fluorescent powder needed in combination with a particular light source to produce a desired lighting result.

In step S1033, the coating on the packaging housing can be cured by way of exposure to air, which is preferably hot and dry, or the packaging housing can be placed in an oven, and residual fluorescent powder on the packaging housing can be removed after the mixed solution evaporates.

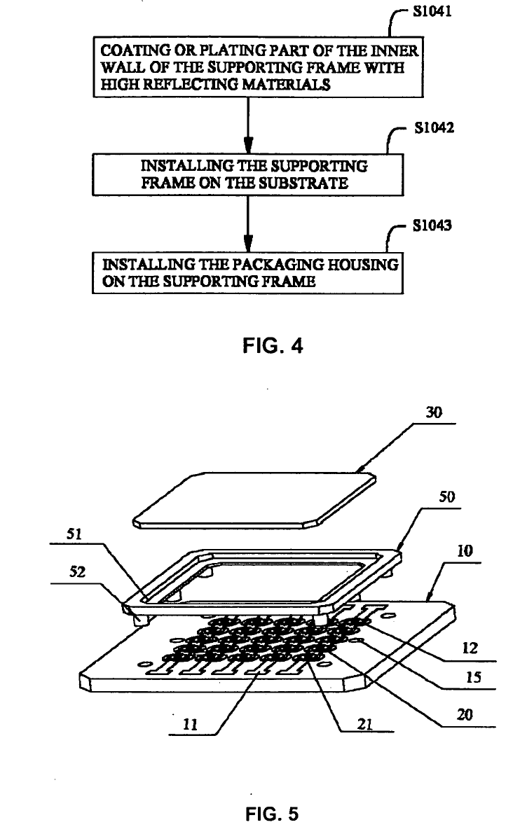

As shown in FIG. 4, in step S1041, all or part of the inner wall of the supporting frame can be coated or plated with high reflecting materials. In another embodiment, this step can also be omitted. In step S1042, the supporting frame can be installed on the substrate. In step S1043, the packaging housing can be installed on the supporting frame. In this embodiment, the packaging housing can be installed on the supporting frame in a manner of interference fit or adhesion. The spacing between the substrate and/or the top surface of the LED chip installed on the substrate and the inner surface of the packaging housing can be adjusted depending on the lighting application. The spacing between the components should allow for a sufficient amount of resin to separate the LED chip from the fluorescent powder and also accommodate a desired fluorescent powder coating thickness. Spacing can be adjusted, for example, to provide for different levels of brightness. In an exemplary embodiment, the spacing between the top surface of the LED chip and the inner surface of the packaging housing could be about 10 microns, which would accommodate a fluorescent powder coating thickness of about 5 microns and allow for a sufficient amount of resin between the components. Likewise, to accommodate a fluorescent powder coating thickness of about 500 microns, the spacing between the top surface of the substrate and the inner surface of the packaging housing should be larger than 500 microns to also provide for a sufficient amount of resin to be present in the cavity between the substrate and packaging housing, depending of course on the application.

The method for packaging a white-light LED of the invention features a simple production process and is especially suitable for mass serial production and packaging having multiple chips, large area, and white light generated by activating fluorescent powder by way of LED chips. Moreover, products produced by the method have good luminous efficiency and heat dissipation performance. In addition, color and brightness of the white light are improved.

FIG. 5 provides an example of an LED device according to the invention comprising an overall square configuration with multiple LED chips arranged in a 5×5 format on a square substrate. As shown in FIG. 5, an LED device of the invention can typically comprise a substrate 10, a plurality of LED chips 20, a packaging housing 30 and a supporting frame 50. In embodiments, as with FIG. 5, LED chips 20 can be installed or disposed on substrate 10. Supporting frame 50 can connect the substrate 10 and the packaging housing 30, support the packaging housing 30, and maintain a desired spacing between the packaging housing 30 and the substrate 10. In this embodiment, the substrate 10 is a printed circuit board with heat sink, a ceramic substrate or a metal circuit board and a cross section thereof is rectangular, while the packaging housing 30 is made of glass, and fluorescent powder is coated on an inner wall thereof. The space between packaging housing 30 and substrate 10 can be filled with resin as means for separating LED chips 20 from the fluorescent powder.

A conductive layer 11 is printed on a top surface and a bottom surface of the substrate 10 (referring to the orientation of the components shown in FIG. 5), and operates to connect external electrodes and an electrode 21 on the LED chip. In another embodiment, optionally the conductive layer 11 is disposed on the top surface of the substrate 10.

An upper surface of the substrate 10 can comprise a plurality of concave parts 12 (depressions), as means for receiving the LED chip 20, which can be formed by an inwardly bent surface. In another embodiment, the concave part 12 is formed by stamping the heat sink, and optionally a reflective cup can be formed by coating the surface of the heat sink with silver. A reflecting layer (not shown) can be disposed on an outer surface of the concave part 12, such as a reflecting layer made of silver and capable of improving light efficiency.

As further shown in FIG. 5, the supporting frame 50 supports the packaging housing 30. In this embodiment, the supporting frame 50 employs cavity structure and is made of plastic, but any equivalent supportive material would suffice. An upper surface of the supporting frame 50 bends inward to form a step 51, and a plurality of positioning pins 52 are disposed on a lower surface of the supporting frame 50. The step 51 operates to support the packaging housing 30. A plurality of positioning holes 15 (optionally corresponding in number with the number of positioning pins 52) are disposed on the substrate 10 and outside the concave part 12, and together cooperate with the positioning pins 52 as means for connecting substrate 10 to supporting frame 50. In this embodiment, the number of positioning pins 52 is equal to that of the positioning holes 15. Further, in this embodiment, the number of the positioning pins 52 is 3, and the positioning pins 52 are symmetrically disposed on both sides of the supporting frame 50, however, any desired placement of positioning pins 52 and corresponding placement of positioning holes 15 can be used. In this embodiment, high reflecting materials are disposed in part of the inner wall of the supporting frame 50 so as to improve light efficiency.

Additionally, in other embodiments, the combination of the substrate and the supporting frame can be in a manner of PLCC packaging, wherein the substrate is a metal frame and the supporting frame is made of plastic. In typical PLCC (plastic leaded chip carrier) packaging, a metal frame (substrate) provides means for supporting one or more LED chips and provides electrical leads for the LED chip(s), while plastic is used to encapsulate the metal frame and can provide means for supporting a packaging housing, such as a lens.

The LED chips 20 are disposed at the bottom of the concave part 12. In this embodiment, the LED chips 20 are blue-light LED chips capable of emitting blue light, and are disposed on the substrate 10 in a matrix to form a planar light source. In another embodiment, the LED chips 20 can be disposed on the substrate 10 in other arrangements, and the number of LED chips 20 may be one.

The outer surface of the packaging housing 30 is typically planar as in this embodiment, and the packaging housing 30 is installed on the step 51 of the supporting frame 50 in a manner of interference fit or adhesion. The outer surface of the packaging housing can also be planar free in some embodiments. Upon installation of the supporting frame 50 and the packaging housing 30 on substrate 10, a closed cavity is formed between the packaging housing 30 and the substrate 10. The size of the cavity will depend on the lighting application.

The fluorescent powder can be disposed on the inner wall of the packaging housing 30 (referring to the surface of the packaging housing 30 that faces the substrate when installed), and is capable of emitting yellow light as being activated by the blue light from the LED chip 20. The yellow light is mixed with part of the blue light passing through the fluorescent powder, and white light generated from the combination emerges from the device. For white-light emitting devices and applications, any type of fluorescent material, such as powder, and LED chip combination can be used, so long as the combination emits white light. For example, a yellow phosphor and blue LED chip(s), or yellow and red phosphors and blue LED chip (s), or green and red phosphors and blue LED chip(s), or RGB (red-green-blue) or multi-colored phosphors and UV LED chip(s) can be used to name a few. Even further, examples of fluorescent powders and light sources that can be used are described in U.S. Pat. Nos. 7,470,935; 7,071,616; 7,026,756; and 6,753,646; and U.S. Published Patent Application No. 2007/0262288, which are herein incorporated by reference in their entireties.

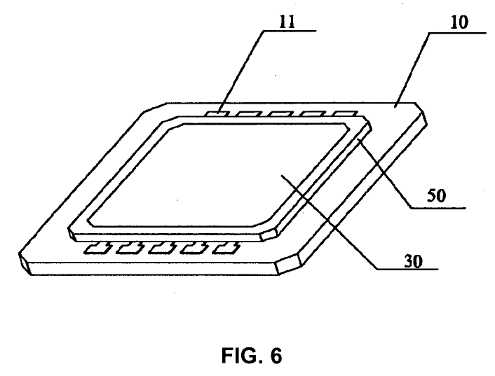

FIG. 6 shows an assembly view of LED components in FIG. 5. In particular, substrate 10 is shown assembled with supporting frame 50 and packaging housing 30. Conductive layer 11, for connection with external electrodes, is shown on substrate 10 partially covered by the installation of packaging housing 30 and supporting frame 50 on substrate 10.

In particular embodiments, the number of the LED chips is not critical and can be any number appropriate for a particular application. For example, the substrate can comprise one or more than one LED chip. Further, for example, when more than one LED chip is desired, the LED chips can be arranged in any order, or format, or matrix desired. Multiple LED chips can be arranged in circular, square, or rectangular configurations if desired.

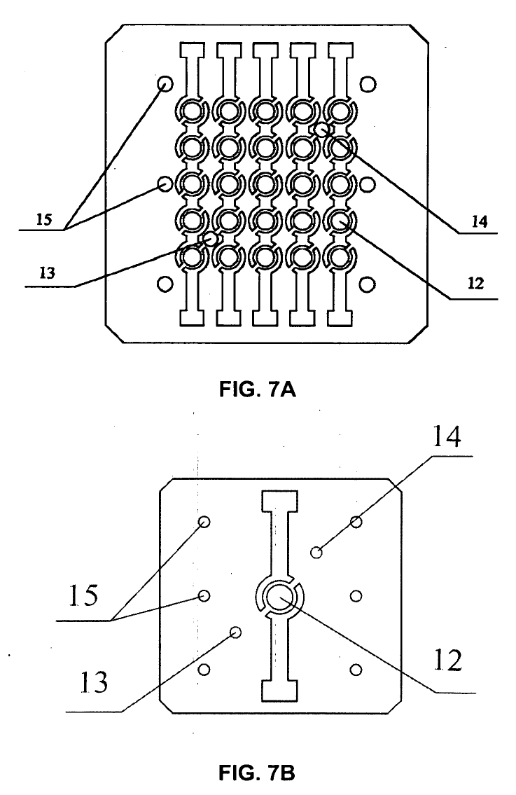

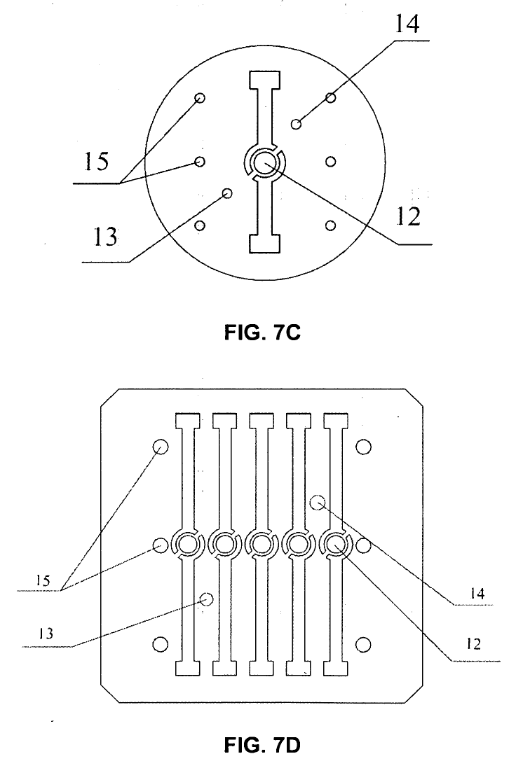

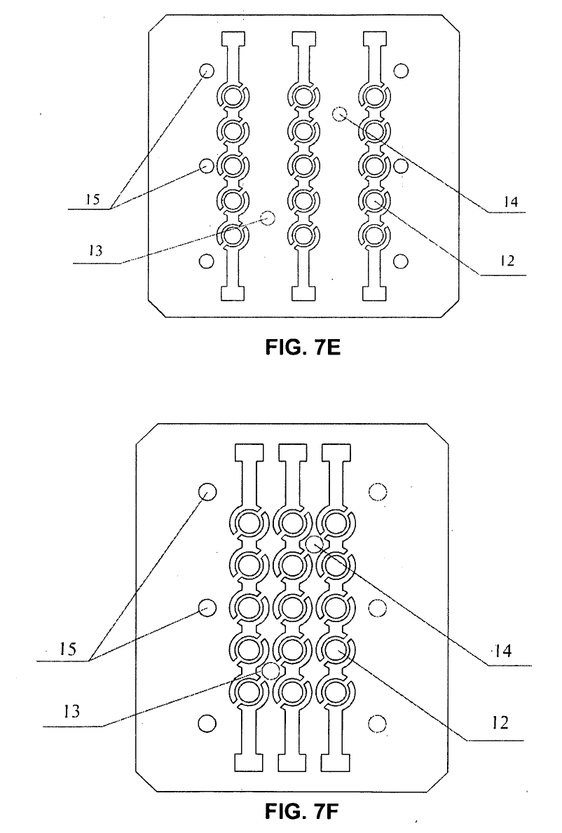

FIGS. 7A-F provide various additional examples of LED devices according to the invention having various arrangements of one or more LED chips. For comparison, concave parts 12 and positioning holes 15 are shown in FIGS. 7A-F, as well as resin injection hole 13 and vent hole 14, which are discussed in detail with respect to FIG. 8 below.

FIG. 7A provides an LED device having an overall square configuration with multiple LED chips arranged in a 5×5 format on a square substrate. Any LED chip format can be used, for example, a 2×1, 3×1, 4×1, 2×2, 3×2, 4×2, 3×3, 4×3 and so on even any and every format up to and beyond 100×100, if suitable for a particular application.

Further, for example, FIG. 7B provides an example of a square substrate comprising a single LED chip. Similarly, FIG. 7C provides an example of a circular substrate comprising a single LED chip.

FIG. 7D provides an example of a square substrate comprising a single row of five LED chips for a 5×1 format. As an example of a 3×5 format, FIG. 7E provides an example of a square substrate comprising three parallel rows of five LED chips. Even further, FIG. 7F provides an example of a rectangular substrate comprising three parallel rows of five LED chips in which the rows are spaced closer together than when compared to the spacing of the LED chip rows of FIG. 7E.

It is important to note that the shape of the substrate does not dictate the multiple LED chip pattern and need not be the same shape as the arrangement of LED chips. Any combination of substrates and LED chips can be used. For example, a circular substrate can comprise multiple LED chips arranged in a rectangular or square configuration, if desired, or a rectangular or square substrate can comprise multiple LED chips in a circular format. If the number of the LED chips is greater than two, the conductive layer can be connected thereto in a manner of serial connection, parallel connection, or a combination thereof.

FIG. 8 provides a schematic view of an exemplary resin injection process according to the invention. Other ways of introducing resin to the LED device are also included within the scope of this invention, so long as the resin provides means for separating the LED chip from the fluorescent powder coating of the packaging housing. In FIG. 8, the cavity between packaging housing 30 (which is shown supported by supporting frame 50 at step 51) and substrate 10 is filled with resin 40, which provides means for separating LED chip(s) 20 from the fluorescent powder. Resin 40 is injected into resin injection hole 13 and pressure is released through vent hole 14, which are both through holes in substrate 10. This overall arrangement separates heat generated from the LED chips and improves heat dispersion and light emission efficiency of the device. In this embodiment, the resin is made of transparent and soft silica.

As shown in FIG. 9, the LED device is almost the same as that shown in FIG. 5, except that a cross section of the substrate 10′ is circular, an outer surface of the packaging housing 30′ is circular, and the LED device forms a circular and planar light source. Also shown on substrate 10′ is conductive layer 11, which provides means for connection of the LED device with external electrodes. As shown, once substrate 10′, packaging housing 30′, and supporting frame 50′ are assembled, conductive layer 11′ is partially exposed.

Benefits of the LED device of the invention include simple structure, which contributes to ease of manufacturing, and uniform chromatic light produced as a result of fluorescent powder disposed on the inner wall of packaging housing 30. In addition, resin 40 disposed between packaging housing 30 and substrate 10 improves heat dispersion and light emission efficiency of the LED device.

The inventive LED assemblies and devices and methods of making them are applicable to a wide variety of applications, including for general illumination purposes, safety and security, signaling, backlighting, signage, decorative lighting, street lighting, and other area lighting, such as wall-mounted flood lights, post-mounted lights, and lights emitting large-area lighting, to name a few. Further, for example, the LED devices can be configured for various types of area lighting by designing the devices to comprise an appropriate number and formatting of the LED chips on the substrate to accommodate a desired range of lighting area. The devices can also be adapted to generate other colors of light in addition to white light by substituting the LED chip(s) and/or fluorescent material(s) accordingly.

The present invention has been described with reference to particular embodiments having various features. It will be apparent to those skilled in the art that various modifications and variations can be made in the practice of the present invention without departing from the scope or spirit of the invention. One skilled in the art will recognize that these features may be used singularly or in any combination based on the requirements and specifications of a given application or design. Other embodiments of the invention will be apparent to those skilled in the art from consideration of the specification and practice of the invention. The description of the invention provided is merely exemplary in nature and, thus, variations that do not depart from the essence of the invention are intended to be within the scope of the invention.

1. A method for packaging a white-light LED, comprising
providing a substrate with at least one resin injection hole and at least one vent hole, a packaging housing, at least one LED chip, a supporting frame, and resin;
installing said at least one LED chip on said substrate;
coating an inner wall of said packaging housing with fluorescent powder;
connecting said packaging housing to said substrate with said supporting frame and forming a cavity between said packaging housing and said substrate;
injecting said resin into said cavity through said at least one resin injection hole and allowing gas within said cavity to discharge through said at least one vent hole; and
curing said resin.

2. The method of claim 1, wherein said installing comprises:
dropping adhesive on a concave part of said substrate;
attaching said at least one LED chip to said adhesive; and
connecting electrodes on said at least one LED chip to a conductive layer on said substrate.

3. The method of claim 1, wherein said coating comprises:
combining inorganic non-baking glue, non-baking consolidant, non-baking dispersants, non-baking plasticizer and fluorescent powder into a fluorescent powder coating mixture;
stirring said mixture, optionally by a ball milling method using ceramic grinding balls;
forming a coating comprising fluorescent powder on said packaging housing by contacting an inner wall of said packaging housing with said mixture, optionally while stirring said mixture to deter separation of said fluorescent powder from said mixture;
exposing said packaging housing coating to a stream of air for a time sufficient to stiffen said coating;
curing said packaging housing coating by exposing said packaging housing to hot and dry air under time and temperature conditions sufficient to cure said coating; and
optionally removing residual fluorescent powder from said packaging housing after drying.

4. The method of claim 1, wherein said connecting comprises:
optionally coating or plating at least part of an inner wall of said supporting frame with reflecting material;
installing said supporting frame on said substrate with means for securing said supporting frame to said substrate; and
installing said packaging housing on said supporting frame with means for securing said packaging housing to said supporting frame.

5. The method of claim 4, wherein said means for securing said packaging housing to said supporting frame or said means for securing said supporting frame to said substrate comprises securing by interference fit.

6. The method of claim 4, wherein said means for securing said packaging housing to said supporting frame comprises securing by adhesion or said means for securing said supporting frame to said substrate comprises securing by PLCC packaging.

7. An LED assembly comprising:
a substrate having at least one resin injection hole, at least one vent hole, and an upper surface;
a packaging housing having an inner surface comprising a fluorescent powder coating;
at least one LED chip disposed on said substrate; and
a supporting frame capable of supporting said packaging housing and connecting said packaging housing to said substrate and providing for a cavity between said packaging housing inner surface and said substrate upper surface when connected;
wherein said cavity is capable of comprising resin for separating said at least one LED chip from said fluorescent powder coating.

8. The LED assembly of claim 7, wherein said substrate upper surface comprises at least one concave depression capable of receiving at least one LED chip and optionally wherein an outer surface of said at least one concave depression is reflective.

9. The LED assembly of claim 7, wherein said substrate is a printed circuit board with heat sink, a ceramic substrate, a metal circuit board, or a metal frame.

10. The LED assembly of claim 7, wherein an upper surface of said supporting frame comprises a stepped surface for supporting said packaging housing.

11. The LED assembly of claim 7, wherein a lower surface of said supporting frame comprises a plurality of positioning pins and said substrate upper surface comprises a corresponding plurality of positioning holes or depressions for securing said supporting frame to said substrate, or said supporting frame is combined with said substrate through PLCC packaging.

12. The LED assembly of claim 7, wherein at least a portion of an inner wall of said supporting frame comprises a reflective coating.

13. The LED assembly of claim 7, wherein said resin comprises transparent and soft silica and wherein said packaging housing comprises glass.

14. The LED assembly of claim 7, wherein an outer surface of said packaging housing is planar free.

15. The LED assembly of claim 7, wherein said substrate comprises a plurality of LED chips arranged in a rectangular or circular format.

16. The LED assembly of claim 7 capable of emitting white light.

17. A white-light LED device comprising:
a substrate comprising an electrically conductive pathway;
at least one LED chip in communication with said pathway;
a packaging housing comprising a fluorescent powder coating;
a supporting frame in communication with said substrate for supporting said packaging housing and maintaining spacing between said substrate and said packaging housing; and
material disposed between said packaging housing and said substrate consisting essentially of resin.

18. The white-light LED device of claim 17, wherein said at least one LED chip is capable of emitting blue light and said fluorescent powder coating comprises yellow phosphor, or yellow and red phosphors, or green and red phosphors, or wherein said at least one LED chip is capable of emitting ultraviolet light and said fluorescent powder coating comprises multi-colored phosphors.

19. An area lighting device comprising the white-light LED device of claim 17.

20. The area lighting device of claim 19 which is a street lighting device.

21. The LED assembly of claim 7, wherein a cross section of said substrate is rectangular or circular.
